(19) United States
(12) Patent Application Publication
(10) Pub. No.: US 2018/0122699 A1
(43) Pub. Date: May 3, 2018

(54) MANUFACTURING METHOD OF ELECTRONIC COMPONENT

(71) Applicant: CANON KABUSHIKI KAISHA, Tokyo (JP)

(72) Inventor: Shin Hasegawa, Hadano-shi (JP)

(21) Appl. No.: 15/728,777

(22) Filed: Oct. 10, 2017

(30) Foreign Application Priority Data
Oct. 31, 2016 (JP) 2016-212780

(51) Int. Cl. H01L 21/768; H01L 21/288; H01L 23/48; H01L 23/528; H01L 23/532; H01L 21/3065; H01L 31/02

(52) U.S. Cl. CPC H01L 21/76898; H01L 21/76879; H01L 21/2885; H01L 23/481; H01L 21/76841; H01L 23/53238; H01L 21/76873; H01L 21/3065; H01L 31/02005; H01L 23/5283

(57) ABSTRACT

Provided is a manufacturing method of an electronic component, the manufacturing method including steps of: preparing a substrate having a first primary surface and a second primary surface, a first conductor layer being disposed on the first primary surface, and the substrate having a through hole arranged to reach the first conductor layer; forming a second conductor layer on the second primary surface, on a side surface of the through hole, and on the first conductor layer located at a bottom of the through hole; and forming a third conductor layer in the through hole by supplying a current from the first conductor layers and the second conductor layers to perform electroplating.

### BACKGROUND OF THE INVENTION

### Field of the Invention

The present invention relates to a manufacturing method of an electronic component.

### Description of the Related Art

As one of the packaging technologies of semiconductor devices, Wafer Level Chip Size Package (WLCSP) is known. WLCSP is a technology of assembling a package with a plurality of semiconductor devices being formed together on a wafer and then singulating it into individual semiconductor devices.

In the WLCSP, through electrode structure may be employed in order to improve a reliability and reduce the size of a semiconductor device. Japanese Patent Application Laid-Open No. 2009-206253 discloses package structure having a through electrode that connects an electrode on the front surface and an electrode on the back surface in a substrate. A signal from a solid state imaging device within a package is output to the outside of the package via the through electrode. In a manufacturing method of semiconductor devices as disclosed in Japanese Patent Application Laid-Open No. 2009-206253, a through electrode is formed by forming a through hole in a substrate and then forming a conductive film inside the through hole.

In the manufacturing of semiconductor devices disclosed in Japanese Patent Application Laid-Open No. 2009-206253, disconnection may occur in a conductive film formed inside a through hole. Thus, such disconnection may cause a conduction failure of the through electrode.

### SUMMARY OF THE INVENTION

A manufacturing method of an electronic component according to one aspect of the present invention including steps of: preparing a substrate having a first primary surface and a second primary surface, a first conductor layer being disposed on the first primary surface, and the substrate having a through hole arranged to reach the first conductor layer; forming a second conductor layer on the second primary surface, on a side surface of the through hole, and on the first conductor layer located at a bottom of the through hole; and forming a third conductor layer in the through hole by supplying a current from the first conductor layers and the second conductor layers to perform electroplating.

Further features of the present invention will become apparent from the following description of exemplary embodiments with reference to the attached drawings.

### BRIEF DESCRIPTION OF THE DRAWINGS

FIG. 1A, FIG. 1B, FIG. 1C, FIG. 1D, FIG. 1E, FIG. 1F and FIG. 1G are sectional views illustrating a manufacturing method of a semiconductor device according to a first embodiment of the present invention.

FIG. 2A, FIG. 2B, FIG. 2C, FIG. 2D, FIG. 2E, FIG. 2F and FIG. 2G are sectional views illustrating a method of forming a through electrode according to a comparative example.

FIG. 3A, FIG. 3B and FIG. 3C are sectional views illustrating a manufacturing method of a semiconductor device according to a second embodiment of the present invention.

FIG. 4A and FIG. 4B are plan views of a semiconductor substrate according to the second embodiment of the present invention.

FIG. 5A, FIG. 5B and FIG. 5C are diagrams illustrating the structure of a singulated semiconductor device according to the second embodiment of the present invention.

FIG. 6A, FIG. 6B and FIG. 6C are sectional views illustrating a manufacturing method of semiconductor devices according to a third embodiment of the present invention.

FIG. 7A and FIG. 7B are diagrams illustrating in detail of formation of a conductor layer in the manufacturing method of the semiconductor device according to the third embodiment of the present invention.

### DESCRIPTION OF THE EMBODIMENTS

Preferred embodiments of the present invention will now be described in detail in accordance with the accompanying drawings. Throughout the drawings, the same members or the same components are provided with the same reference numerals. Further, in the following embodiments, duplicated description may be omitted or simplified.

### First Embodiment

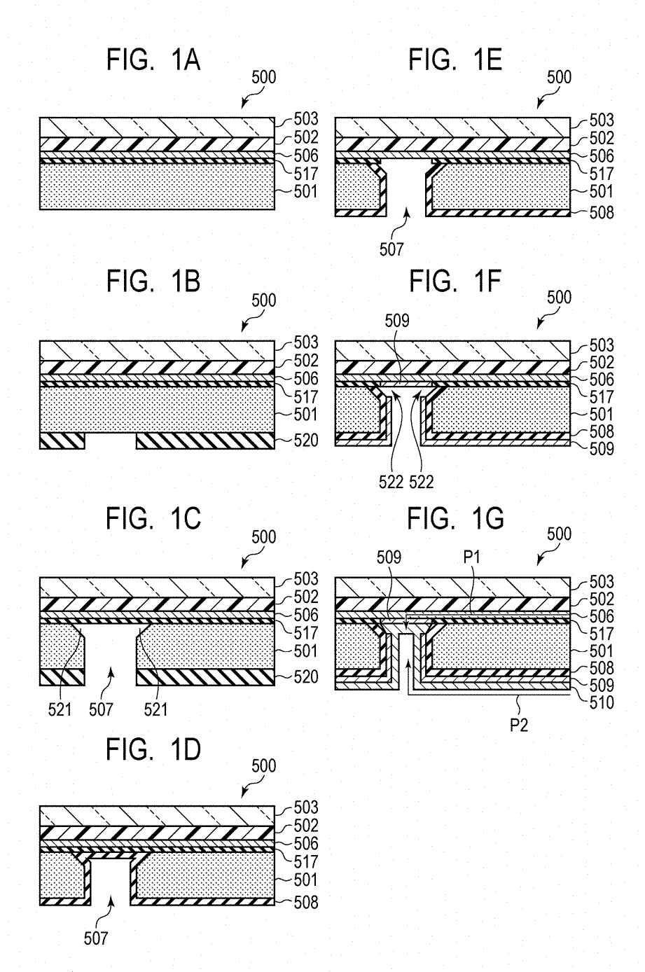

FIG. 1A to FIG. 1G are sectional views illustrating an example of a manufacturing method of a semiconductor device 500 according to a first embodiment of the present invention. FIG. 1A to FIG. 1G are schematic diagrams illustrating the outline of a method of forming a through electrode and depict only a portion near a through hole 507. Further, depiction of a component which is unnecessary in illustrating a method of forming a through electrode may be omitted, and the semiconductor device 500 may further include elements other than the depicted elements. A known semiconductor manufacturing process may be used in manufacturing of the semiconductor device 500. Further, FIG. 1A to FIG. 1G do not necessarily illustrate all the required steps, and some not-illustrated process such as a heat treatment, a cleaning process, or the like may be performed within each step or between respective steps if necessary.

FIG. 1A is a diagram illustrating a step of preparing the semiconductor device 500 including a semiconductor substrate 501. The semiconductor device 500 is a solid state imaging device such as a Complementary Metal Oxide Semiconductor (CMOS) image sensor or the like. The solid state imaging device is a device that includes a photoelectric conversion element such as a photodiode and thereby outputs an electrical signal from an incident light. The semiconductor device 500 has the structure in which a semiconductor substrate 501, which is a first substrate (substrate), and a support substrate 503, which is a second substrate (another substrate), are joined.

The semiconductor substrate 501 has an insulating layer 517 formed on a first primary surface (hereafter, referred to as a front surface) that is a surface of the upper side in FIG. 1A. A conductor layer 506 (first conductor layer) is disposed on the front surface. The support substrate 503 is joined by an adhesion member 502 so as to face the front surface of the semiconductor substrate 501. Although depicted as each single layer, the conductor layer 506 and the insulating layer 517 may be multilayered wiring layers.

While a silicon substrate may typically be used for the semiconductor substrate 501, the semiconductor substrate 501 may be another semiconductor substrate such as a compound semiconductor substrate. The primary material of the conductor layer 506 is a metal such as aluminum, a copper, or the like, for example. Since the semiconductor substrate 501 is non-insulating, the conductor layer 506 is not formed directly on the front surface of the semiconductor substrate 501 but is formed via the insulating layer 517. Another insulating layer may be formed on a surface opposite to the semiconductor substrate 501 of the conductor layer 506 in a similar manner.

The adhesion member 502 is a member that, when adhering the semiconductor substrate 501 and the support substrate 503, forms a cavity accommodating a semiconductor element formed on the semiconductor substrate 501. An epoxy resin, an acrylic resin, a silicone resin, or the like may be used for the adhesion member 502, for example.

When the semiconductor device 500 includes a photoelectric conversion element, the support substrate 503 is preferably a substrate having an optical transparency, such as a glass of a quartz glass or the like, a crystal quartz, a plastic, or the like for transmitting an incident light. Furthermore, when the semiconductor substrate 501 is a silicon substrate in order to form a photoelectric conversion element, it is more preferable that the support substrate 503 be a glass with a composition whose linear expansion coefficient is close to that of a silicon for reducing an influence of a thermal stress caused by a difference of the linear expansion coefficients.

FIG. 1B is a diagram illustrating a step of forming an etching mask 520 on a second primary surface (hereafter, referred to as a back surface) that is a surface of the underside of the semiconductor substrate 501. FIG. 1C is a diagram illustrating a step of forming the through hole 507 (through hole) having a cylindrical shape or the like by using the etching mask 520 as a mask by ion etching such as Reactive Ion Etching (RIE) or the like. The RIE may include Capacitive Coupled Plasma-RIE (CCP-RIE) and Inductive Coupled Plasma-RIE (ICP-RIE). Further, so called a Bosch process may be used for the RIE process, or other process may be used. Here, since the insulating layer 517 is present on the bottom of the through hole 507, ions that entered the insulating layer 517 at ion etching cause the insulating layer 517 to be charged. The ions that entered the through hole 507 afterward are repelled by the charged insulating layer 517 and etch the semiconductor substrate 501 in the lateral direction, and thereby notches 521 are formed around the bottom of the through hole 507.

FIG. 1D is a diagram illustrating a step of forming the insulating layer 508 on the inner surface of the through hole 507 and the back surface of the semiconductor substrate 501 after removing the etching mask 520. FIG. 1E is a diagram illustrating a step of removing the insulating layers 508 and 517 on the bottom of the through hole 507 and exposing an opening on the conductor layer 506 at the bottom of the through hole 507. As discussed above, the semiconductor substrate 501 having the through hole 507 formed so as to penetrate the semiconductor substrate 501 from the back surface and reach the conductor layer 506 is provided.

FIG. 1F is a diagram illustrating a step of forming the conductor layer 509 (second conductor layer) on the conductor layer 506 located on the back surface of the semiconductor substrate 501, on the insulating layer 508 on the side surface of the through hole 507, and on the bottom surface of the through hole 507 (at a bottom of the through hole 507). The conductor layer 509 is a seed metal (seed layer) used as a seed in electroplating. The conductor layer 509 may be a multilayer film in which a barrier metal (barrier layer) for reducing diffusion of a metal and a seed metal are layered. For example, at least one of a titanium, a titanium nitride, a tantalum, and a tantalum nitride may be used for the barrier metal. The barrier metal may be a multilayer film of two or more of a titanium, a titanium nitride, a tantalum, and a tantalum nitride. For example, at least one of a copper and a ruthenium may be used for the seed metal. The seed metal may be a multilayer film of a copper and a ruthenium. As illustrated in FIG. 1F, disconnections 522 of the conductor layer 509 may occur in the portions where the notches 521 are formed.

FIG. 1G is a diagram illustrating a step of forming the conductor layer 510 (third conductor layer) whose primary material is a copper by performing electroplating of a copper using the conductor layer 509 as a seed. In this step, in performing the electroplating, a current is supplied from both of two paths of a current path P1 (first path) that passes through at least the conductor layer 506 of a portion other than the through hole 507 and a current path P2 (second path) that passes through the conductor layer 509. Thereby, the conductor layer 510 grows from both the conductor layer 509 formed on the bottom of the through hole 507 and the conductor layer 509 formed on the side surface of the through hole 507. Thus, as illustrated in FIG. 1G, the conductor layer 510 is formed over the portion of the disconnection 522 and thereby the bottom and the side surface of the through hole 507 are connected by the conductor layer 510, which eliminates a conduction failure due to the disconnection 522.

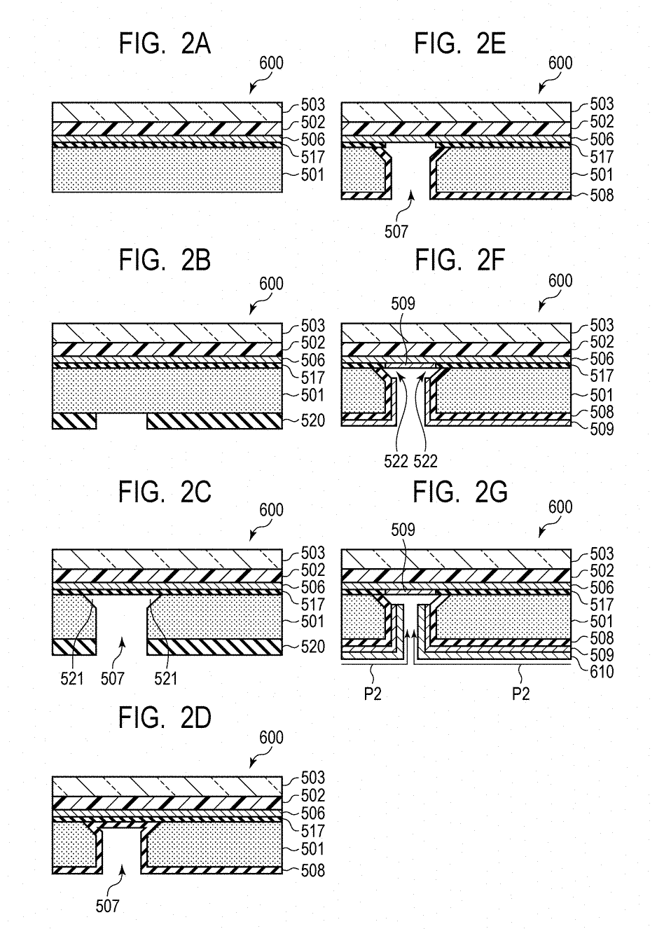

Next, with reference to FIG. 2A to FIG. 2G, a method of forming a through electrode when a single current supply path is provided will be described as a comparative example to the present embodiment. FIG. 2A to FIG. 2G are sectional views illustrating a manufacturing method of a semiconductor device 600 according to the comparative example. Since the steps of FIG. 2A to FIG. 2F are the same as those of FIG. 1A to FIG. 1F described above, the description thereof will be omitted.

FIG. 2G is a diagram illustrating a step of forming a conductor layer 610 by electroplating using the conductor layer 509 as a seed. In the step of electroplating, a current is supplied from the external of the through hole 507 to the inside of the through hole 507 as illustrated as the current path P2 in FIG. 2G. At this time, since the conductor layer 509 on the bottom of the through hole 507 is the downstream of the disconnection 522, no current is supplied to the conductor layer 509 on the bottom of the through hole 507. Therefore, no growth of the conductor layer due to the electroplating occurs in the conductor layer 509 on the bottom of the through hole 507, and the conductor layer 610 is not formed thereon. Thus, as illustrated in FIG. 2G, the disconnection 522 may cause a conduction failure of the through electrode.

As discussed above, when a single current supply path is provided as seen in the comparative example, a conduction failure may occur in a through electrode due to the notch 521 that may be formed when the through hole 507 is formed. In contrast, as discussed above, the manufacturing method of the semiconductor device 500 according to the present embodiment includes the step of supplying a current from two current supply paths to perform electroplating. This allows for a reduction in occurrence of a conduction failure of a through electrode due to the notch 521 that may be formed when the through hole 507 is formed.

Note that, the present invention is not limited to manufacturing of a semiconductor device using a semiconductor substrate but is applicable to manufacturing of any electronic component as long as it has a through electrode in which a conductor layer is formed inside the through hole by electroplating. Here, “electronic component” described above may include a semiconductor device with the WLCSP structure, a semiconductor device having Through Silicon Via (TSV), a packaging member having a through electrode structure, a wiring board such as a printed wiring board, and the like. For example, the present invention can be applied to manufacturing of a printed wiring board by replacing the semiconductor device 500 of the present embodiment with a printed wiring board and replacing the through hole 507 with a via for obtaining conduction between layers of the printed board. Also in this modified example, it is possible to reduce occurrence of a conduction failure due to an uneven shape inside a through hole generated when the through hole is formed.

### Second Embodiment

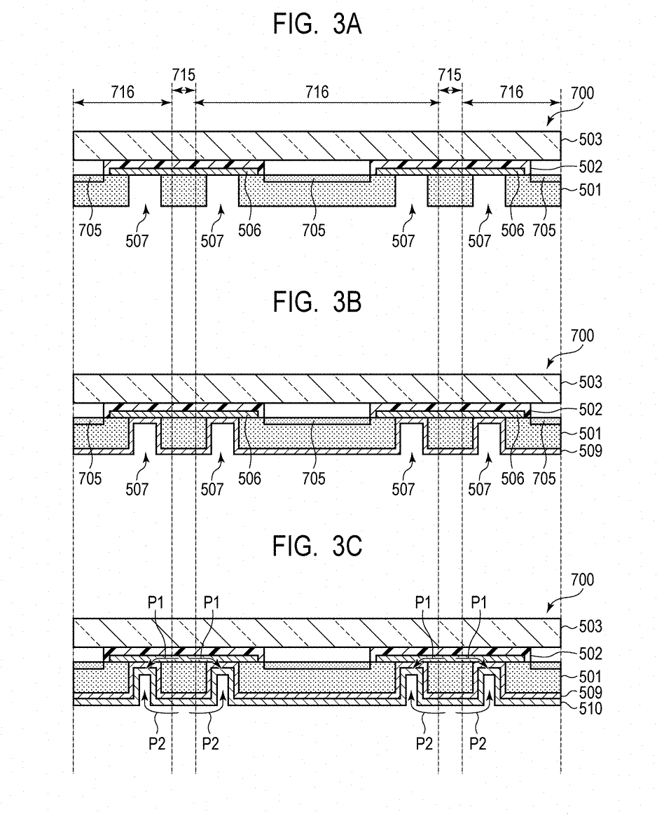

FIG. 3A to FIG. 3C are sectional views illustrating one example of a manufacturing method of a semiconductor device 700 according to a second embodiment of the present invention. The semiconductor device 700 has the WLCSP structure in which the semiconductor substrate 501, which is a first substrate, and the support substrate 503, which is a second substrate, are joined by the adhesion member 502. The semiconductor device 700 is manufactured by a method of forming a plurality of semiconductor devices 700 together on a wafer and performing singulation after the completion of packaging. In the present embodiment, the manufacturing method of the semiconductor device 700 with the WLCSP structure having an external terminal of a Ball Grid Array (BGA) will be more specifically described mainly for features different from the first embodiment.

FIG. 3A illustrates a step of preparing the semiconductor device 700 in which the semiconductor substrate 501 and the support substrate 503 are joined by the adhesion member 502. A plurality of semiconductor elements 705 are formed on the front surface of the semiconductor substrate 501. Each semiconductor element 705 includes a photoelectric conversion element such as a photodiode, a transistor, or the like, for example. The semiconductor element 705 and the conductor layer 506 are connected to each other by a wiring (not illustrated) on the front surface of the semiconductor substrate 501.

In a top view from a direction perpendicular to the primary surface of the semiconductor substrate 501, the semiconductor substrate 501 is divided into a plurality of function regions 716 in each of which the semiconductor element 705 and the through hole 507 are formed and scribe regions 715 which are the outside regions of the function regions 716. Each scribe region 715 includes a region to be cut by a process such as dicing or the like when the wafer of the semiconductor substrate 501 is singulated. The conductor layer 506 extends from the function region 716 to the scribe region 715.

The adhesion member 502 is formed so as to surround the semiconductor element 705 in a frame-like shape and cover the through hole 507 in a top view from a direction perpendicular to the primary surface of the semiconductor substrate 501. A region surrounded by the semiconductor substrate 501, the adhesion member 502, and the support substrate 503 defines a cavity. When the semiconductor element 705 includes a photoelectric conversion element, the adhesion member 502 is preferably a black light-shielding resin for absorbing an unnecessary incident light and further is preferably an epoxy resin for improving a humidity resistance.

Note that, although the insulating layer 517 may be formed on the front surface of the semiconductor substrate 501 as seen in the first embodiment also in the present embodiment, the depiction thereof is omitted in FIG. 3A to FIG. 3C for simplified illustration. Similarly, although the insulating layer 508 may be formed on the back surface of the semiconductor substrate 501 and the inner surface of the through hole 507, the depiction thereof is omitted in FIG. 3A to FIG. 3C for simplified illustration. Furthermore, depiction of notches that may be formed inside the through hole 507 is omitted in FIG. 3A to FIG. 3C for simplified illustration.

FIG. 3B is a diagram illustrating a step of forming the conductor layer 509 on the back surface of the semiconductor substrate 501, the inner surface of the through hole 507, and the bottom surface of the through hole 507. Since this is the same step as that of FIG. 1F, the description thereof will be omitted.

FIG. 3C is a diagram illustrating a step of forming the conductor layer 510 containing a copper by performing electroplating of a copper using the conductor layer 509 as a seed. In the electroplating, a current is supplied from both of the two paths of the current path P1 passing through at least the conductor layer 506 of a portion other than the through hole 507 and the current path P2 passing through the conductor layer 509. Here, the current path P1 is a path passing through the conductor layer 506 of the scribe region 715. Further, the current path P2 is a path passing through the conductor layer 509 of the scribe region 715. Also in the present embodiment, occurrence of a conduction failure of a through electrode due to a notch can be reduced in a similar manner to the first embodiment.

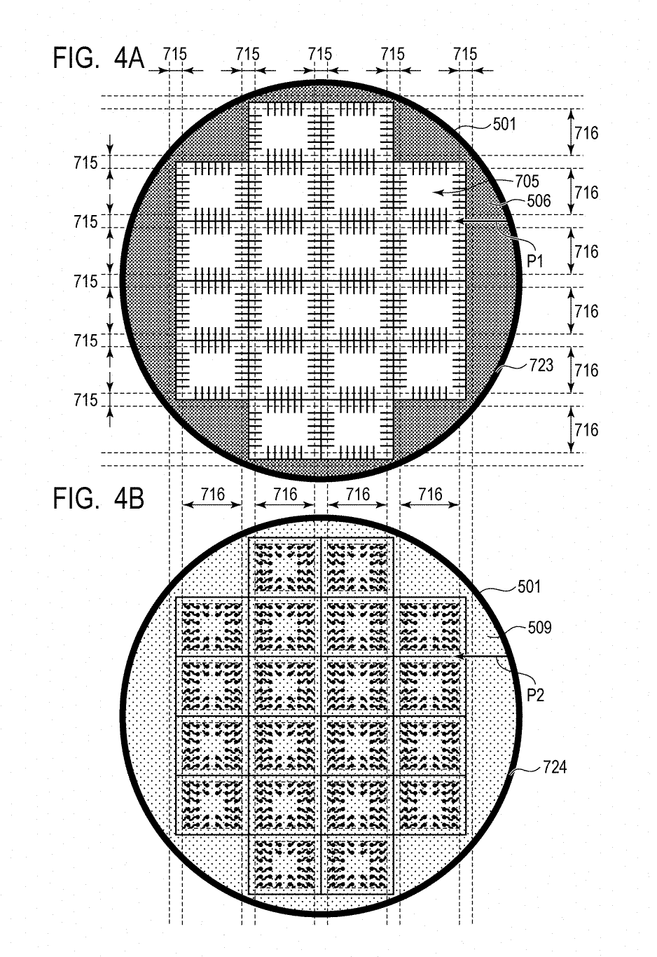

Next, with reference to FIG. 4A and FIG. 4B, a specific method of supplying a current from two paths will be described. FIG. 4A and FIG. 4B are plan views of the semiconductor substrate 501 before singulation, according to the second embodiment of the present invention. FIG. 4A is a perspective plan view of the wafer of the semiconductor substrate 501 when viewed from the front surface side through the support substrate 503. Since FIG. 4A is a perspective view, the support substrate 503 is not depicted in FIG. 4A. FIG. 4B is a plan view of the wafer of the semiconductor substrate 501 when viewed from the back surface side.

In FIG. 4A, a plurality of function regions 716 aligned in a matrix are provided on the semiconductor substrate 501. Regions between the plurality of function regions 716 are the scribe regions 715 to be removed by dicing or the like in singulation. A current supply portion 723 for supplying a current from a power source in a step of electroplating is formed in the outer circumference of the semiconductor substrate 501. The current from the current supply portion 723 is supplied to each of the function regions 716 via the current path P1 that passes through the conductor layer 506 of the scribe region 715.

In FIG. 4B, a current supply portion 724 for supplying a current from a power source in a step of electroplating is formed in the outer circumference of the semiconductor substrate 501. The current from the current supply portion 724 is supplied to each of the function regions 716 via the current path P2 that passes through the conductor layer 509 of the scribe region 715. Note that the conductor layer 509 in the portion other than the function regions 716 and the current supply portion 724 may be covered with a resist (not illustrated). In this case, in the step of electroplating, it is possible not to grow a deposition film on a portion such as the scribe region 715 or the like where no deposition is needed in the step of electroplating, which allows for efficiently performing the step of electroplating.

Note that, while arranged in the outer circumference of the semiconductor substrate 501 in FIG. 4A and FIG. 4B, the current supply portions 723 and 724 may have any shape without being limited thereto as long as they can supply a current.

In the present embodiment, the current supply portion 723 for supplying a current via the current path P1 is formed on the front surface of the semiconductor substrate 501 and the current supply portion 724 for supplying a current via the current path P2 is formed on the back surface of the semiconductor substrate 501. This allows for current supply via the current paths P1 and P2 from the outer circumference of the semiconductor substrate 501. Further, in the present embodiment, the conductor layers 506 of the function regions 716 are arranged to be commonly connected by the conductor layers 506 of the scribe regions 715 and thus connected to each other at the same potential before singulated. This allows for an additional advantage that the semiconductor element 705 is less likely to be damaged due to charging in a process of using plasma, ions, or the like such as etching.

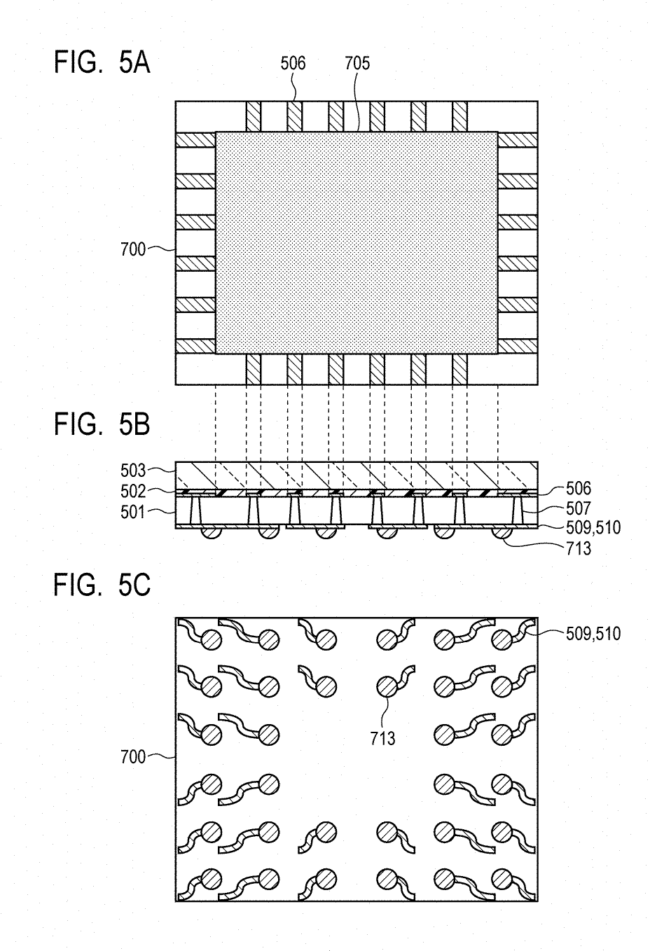

FIG. 5A to FIG. 5C are diagrams illustrating the structure of the semiconductor device 700 after singulation. The semiconductor device 700 illustrated in FIG. 5A to FIG. 5C is obtained by mounting solder balls to form the external terminals 713 after the steps of FIG. 3A to FIG. 3C and then removing the scribe regions 715 by dicing or the like for singulation.

FIG. 5A is a perspective plan view of the semiconductor device 700 when viewed from the front surface side of the semiconductor substrate 501 through the support substrate 503. Removal of the scribe region 715 results in a separated conductor layer 506 extending from the semiconductor element 705.

FIG. 5B is a side view of the semiconductor device 700. The conductor layer 506 formed on the front surface of the semiconductor substrate 501 and the conductor layers 509 and 510 formed on the back surface are connected to each other by the through electrodes formed in the through holes 507 (the conductor layers 509 and 510 formed on the inner surface and the bottom surface of the through holes 507). Further, the external terminals 713 with the BGA structure formed by using solder balls are formed on the conductor layer 510. Note that, in FIG. 5B, the conductor layer 506 and the through hole 507 are depicted as a perspective view through the semiconductor substrate 501.

FIG. 5C is a plan view of the semiconductor device 700 when viewed from the back surface side of the semiconductor substrate 501. A rewiring layer formed of the conductor layers 509 and 510 is arranged so as to connect the through holes 507 and the external terminals 713.

As discussed above, in the present embodiment, the conductor layer 506 is shared in the scribe region 715. This allows the conductor layer 506 to function as a current path in an electroplating step before singulation and then function as a separate electrode after singulation. Furthermore, in addition to the advantages of the first embodiment, an additional advantage that the semiconductor element 705 is less likely to be damaged due to charging is obtained.

### Third Embodiment

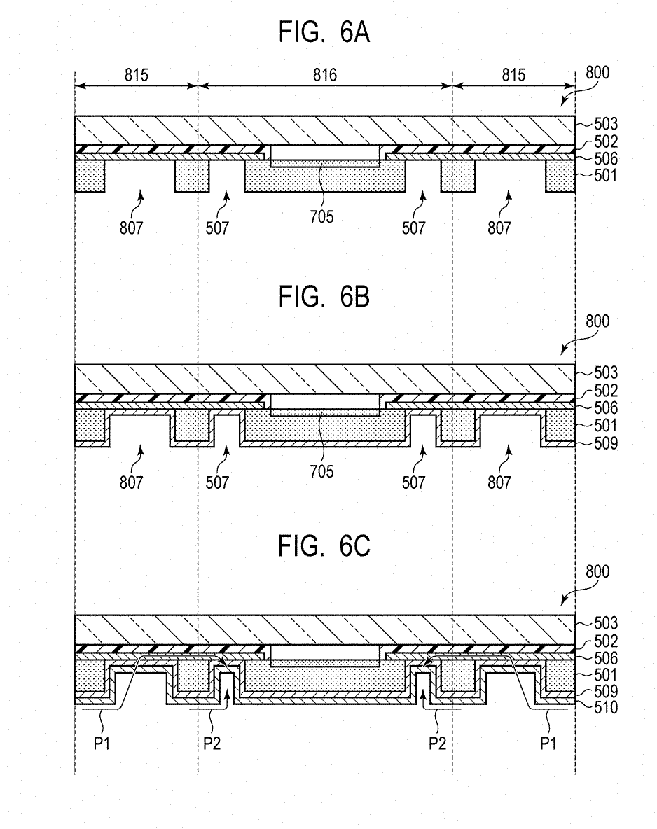

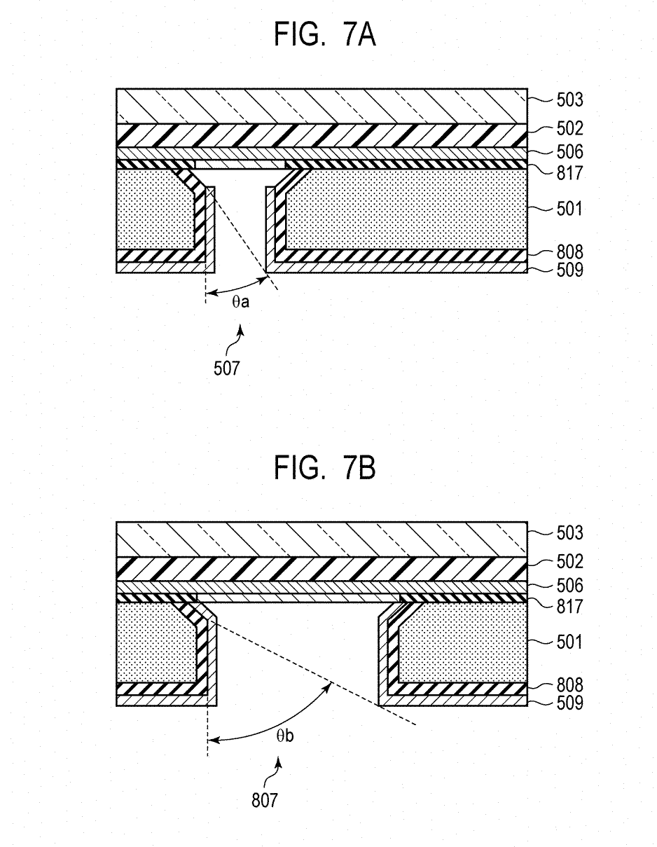

While a third embodiment will be described below with reference to FIG. 6A to FIG. 6C and FIG. 7A and FIG. 7B, the description of features common to the first embodiment or the second embodiment will be omitted. FIG. 6A to FIG. 6C are sectional views illustrating one example of a manufacturing method of a semiconductor device 800 according to the third embodiment of the present invention.

FIG. 6A is a step of preparing the semiconductor device 800 in which the semiconductor substrate 501 and the support substrate 503 are joined by the adhesion member 502. The present embodiment is different from the second embodiment in that, in addition to the through holes 507 formed in a function region 816, through holes 807 (another through hole) are further formed in the scribe regions 815. The conductor layer 506 is exposed as an opening at the bottom of the through hole 807 in a similar manner to the bottom of the through hole 507. Further, the through hole 807 has a greater width than the through hole 507, in other words, the area of the through hole 807 is larger than the area of the through hole 507.

FIG. 6B is a diagram illustrating a step of forming the conductor layer 509 on the back surface of the semiconductor substrate 501, the inner surfaces of the through holes 507 and 807, and the bottom surfaces of the through holes 507 and 807.

With reference to FIG. 7A and FIG. 7B, the details of the step of forming the conductor layer 509 will now be described. FIG. 7A and FIG. 7B are diagrams illustrating the details of the step of forming the conductor layer 509. FIG. 7A is an enlarged view around the through hole 507, and FIG. 7B is an enlarged view around the through hole 807. When the conductor layer 509 is formed on an insulating layer 808 by using a deposition method such as sputtering, only particles which enter the through hole 507 at a small incident angle θa can reach a portion near the bottom of the through hole 507 because of the small width of the through hole 507, as illustrated in FIG. 7A. Thus, the portion of a notch is shaded and the conductor layer 509 is not formed causing a disconnected portion to occur. On the other hand, since the through hole 807 has a greater width than the through hole 507, the incident angle θb of a particle which can reach a portion near the bottom of the through hole 807 is larger than the incident angle θa, as illustrated in FIG. 7B. Therefore, even when a notch occurs, the portion of the notch is less likely to be shaded with respect to the incident particle, and a disconnection is less likely to occur in the through hole 807 than in the through hole 507.

FIG. 6C is a diagram illustrating a step of forming the conductor layer 510 containing a copper by performing electroplating of a copper using the conductor layer 509 as a seed. In this step, the difference from the second embodiment is in the current path P1 that supplies a current for electroplating. In the present embodiment, since the through hole 807 is formed in the scribe region 815 to function as a through electrode, the current path P1 is a path that branches from the current path P2 passing through the back surface of the semiconductor substrate 501, enters the through hole 807, and reaches the conductor layer 806.

As discussed above, by forming the through hole 807 in the scribe region 815, it is possible to branch the current path passing through the back surface of the semiconductor substrate 501 into the current path P1 and the current path P2. Thereby, a current supply portion for supplying a current in electroplating can be shared to omit the current supply portion 723 or the current supply portion 724 in FIG. 4B. Therefore, according to the present embodiment, in addition to the advantages of the first embodiment and the second embodiment, the shared current supply portion for the current paths P1 and P2 allows for an additional advantage of a reduction in the number of steps, a reduction in cost, or the like.

Note that a plurality of through holes 807 may be formed in the scribe region 815 illustrated in FIG. 6A to FIG. 6C, and the plurality of through holes 807 may be further coupled. In this case, the plurality of through holes 807 are formed in a groove-like shape along a line to be cut when the semiconductor substrate 501 is singulated, and form a through groove. When the semiconductor substrate 501 is a silicon substrate or the like including photoelectric conversion elements and the support substrate 503 is a glass, it may be necessary to perform multiple times of dicing when dicing these substrates. This is because a dicing blade used for cut the semiconductor substrate and a dicing blade used for cut the glass substrate may be different from each other. By forming the through groove within the scribe region 815 so as to surround the function region 816, however, since a part of the semiconductor substrate 501 is cut in advance, it is possible to reduce or eliminate the amount of the semiconductor substrate to be cut off in a dicing step. It is therefore possible to performing singulation by a single step using a dicing blade for a glass substrate, which allows for an additional advantage of a reduction in the number of steps, a reduction in cost, or the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2016-212780, filed Oct. 31, 2016, which is hereby incorporated by reference herein in its entirety.

What is claimed is:

1. A manufacturing method of an electronic component, the manufacturing method comprising steps of:
preparing a substrate having a first primary surface and a second primary surface, a first conductor layer being disposed on the first primary surface, and the substrate having a through hole arranged to reach the first conductor layer;
forming a second conductor layer on the second primary surface, on a side surface of the through hole, and on the first conductor layer located at a bottom of the through hole; and
forming a third conductor layer in the through hole by supplying a current from the first conductor layers and the second conductor layers to perform electroplating.

2. The manufacturing method of the electronic component according to claim 1, wherein the substrate is a semiconductor substrate having a semiconductor element arranged in the first primary surface.

3. The manufacturing method of the electronic component according to claim 1,
wherein the substrate further has
a function region including the through hole in a top view, and
a scribe region provided outside the function region and including a region to be cut when singulating the substrate in the top view,
wherein the first conductor layer extends from the function region to the scribe region, and
wherein the current is supplied via the first conductor layer of the scribe region.

4. The manufacturing method of the electronic component according to claim 3,
wherein the substrate has a plurality of function regions, and
wherein the first conductor layer of one of the plurality of the function regions and the first conductor layer of another of the plurality of the function regions are commonly connected in the scribe region.

5. The manufacturing method of the electronic component according to claim 1, wherein the substrate further has another through hole, and the first conductor layer is conducted to a conductor layer located at a bottom of the another through hole.

6. The manufacturing method of the electronic component according to claim 5, wherein an area of the another through hole is larger than an area of the through hole.

7. The manufacturing method of the electronic component according to claim 5, wherein the another through hole is formed in a groove-like shape along a line to be cut when the substrate is singulated.

8. The manufacturing method of the electronic component according to claim 1, wherein the second conductor layer includes a plurality of layers.

9. The manufacturing method of the electronic component according to claim 1, wherein the second conductor layer includes a barrier layer that reduces diffusion of a metal and a seed layer that is used as a seed in the electroplating.

10. The manufacturing method of the electronic component according to claim 9, wherein the barrier layer includes at least one of a titanium, a titanium nitride, tantalum, and a tantalum nitride.

11. The manufacturing method of the electronic component according to claim 9, wherein the seed layer includes at least one of a copper and a ruthenium.

12. The manufacturing method of the electronic component according to claim 1, wherein the third conductor layer includes a copper.

13. The manufacturing method of the electronic component according to claim 1, wherein the through hole is a hole formed by ion-etching.

14. The manufacturing method of the electronic component according to claim 1, wherein a notch is formed inside the through hole.

15. The manufacturing method of the electronic component according to claim 1, wherein the substrate further has an insulating layer formed between the second conductor layer and the substrate.

16. The manufacturing method of the electronic component according to claim 1, wherein, in the step of preparing the substrate, another substrate is joined to the substrate so as to face the first primary surface.

17. The manufacturing method of the electronic component according to claim 16,
wherein the substrate includes a photoelectric conversion element, and
wherein the another substrate has an optical transparency.

18. The manufacturing method of the electronic component according to claim 1, wherein, in the step of forming the third conductor layer, the electroplating is performed by supplying the current from both of a first path passing through the first conductor layer and a second path passing through the second conductor layer.
